(19) United States
(12) Patent Application Publication
(10) Pub. No.: US 2001/0045873 A1
(43) Pub. Date: Nov. 29, 2001

(54) Noise reduction circuit and semiconductor device including the same

(76) Inventors: Miki Suzuki, Kawasaki-shi (JP); Hideo Nunokawa, Kawasaki-shi (JP)

Correspondence Address: STAAS & HALSEY LLP, 700 11TH STREET, NW, SUITE 500, WASHINGTON, DC, 20001, US

(21) Appl. No.: 09/774,688

(22) Filed: Feb. 1, 2001

(30) Foreign Application Priority Data
May 29, 2000 (JP) 2000-158654

(51) Int. Cl. H03H 7/06

(52) U.S. Cl. 333/12; 333/172

(57) ABSTRACT

The present invention relates to a noise reduction circuit suitably used for an in-vehicle electronic equipment requiring an EMI countermeasure and a semiconductor device including the noise reduction circuit, and has an object to provide a noise reduction circuit which can reduce undesired radiant noise generated from a semiconductor device and a semiconductor device including the noise reduction circuit. An LSI chip 1 includes a power supply terminal 4 for supplying an external power supply voltage to an internal circuit 2 including a circuit operating in synchronization with a clock, and a ground terminal 6 for giving a ground potential. Further, the LSI chip 1 includes a noise reduction circuit which includes a plurality of low-pass filters LPF constituted by resistor elements RS1 to RSn and RG1 to RGn and MOS capacitors CS1 to CSn and CG1 to CGn inserted between the power supply terminal 4 and the internal circuit 2 and between the ground terminal 6 and the internal circuit 2, and reduces the undesired radiant noise transmitted from the internal circuit 2.

### BACKGROUND OF THE INVENTION

1. Field of the Invention

The present invention relates to a noise reduction circuit for use in reducing undesired radiant noise in electromagnetic wave interference (ElectroMagnetic Interference; EMI) and a semiconductor device including the noise reduction circuit, and particularly to a noise reduction circuit suitably used for an in-vehicle electronic equipment requiring an EMI countermeasure and a semiconductor device including the noise reduction circuit.

2. Description of the Related Art

In recent years, an LSI chip (semiconductor device) on which an LSI (Large Scale Integrated circuit) operating in synchronization with a clock such as a microcomputer or an ASIC (IC for special use) is mounted, has been used forvarious devices. For example, a car navigation system as an in-vehicle electronic equipment has a built-in LSI chip on which a microcomputer or an ASIC operating at a fundamental clock frequency of several tens MHz is mounted. However, since a harmonic component of the fundamental clock frequency of a clock pulse for operating the microcomputer or the ASIC overlaps with, for example, a frequency of an FM band (66 MHz to 108 MHz) used in an in-vehicle radio, in order to keep the quality of the in-vehicle radio, it becomes necessary to take an EMI countermeasure to reduce undesired radiation noise of the harmonic component.

A conduction route of the undesired radiant noise includes (1) a wiring line on an LSI chip, a wiring line connected to an LSI through a lead frame, or (2) a power supply line for supplying power to the LSI or a ground line. Among these, with respect to (1), by devising the arrangement of a wiring pattern on a substrate or providing a low-pass filter or the like to the wiring line, the improvement of reducing the undesired radiant noise from that has been conventionally made. However, as a circuit pattern of the LSI becomes fine and an operation clock frequency is raised in recent years, there occurs a state where desired noise reduction can not be achieved by only the EMI countermeasure as to (1). On this account, although it is also conceivable to shield the whole substrate, on which the LSI chip is mounted, with a metal plate, since this causes an increase in costs, there is a problem that it is hard to adopt this.

Then, in recent years, attention has been paid to reduction of noise conduction from the power supply line of (2). The LSI chip is connected to an external power supply through a power supply line, and the power supply line has essentially low impedance. On this account, the power supply line has a complete condition convenient for the conduction route of the undesired radiant noise, and it can not be neglected as a noise conduction route to be improved. Then, by inserting a low-pass filter between a power supply terminal of the LSI chip and an internal circuit, a high frequency noise generated from the power supply terminal of the LSI chip is reduced.

FIG. 6 schematically shows the vicinities of a power supply terminal 104 and a ground terminal 106 of a conventional LSI chip. An internal circuit 102 has a not-shown built-in clock generator (oscillator) and includes a circuit operating in synchronization with a clock. A power supply line 108 is extended from the internal circuit 102 and is connected to the power supply terminal 104. A ground line 110 is extended from the internal circuit 102 and is connected to the ground terminal 106.

N resistors R1 to Rn are connected in series with the power supply line 108. A capacitor (hereinafter referred to as a MOS capacitor) C1 formed by using a gate capacitance of a MOSFET (Metal-Oxide Semiconductor Field Effect Transistor) is disposed between a connection point between the resistors R1 and R2 and the ground line 110. A gate electrode of the MOS capacitor C1 is connected to the connection point between the resistors R1 and R2, and source/drain electrodes of the MOS capacitor C1 are shorted and are connected to the ground line 110. A low-pass filter LPF1 is constituted by a CR circuit of the resistor R1 and the MOS capacitor C1.

In the same way, low pass filters LPF2 to LPFn are respectively constituted by the resistor R2 and the MOS capacitor C2, . . . , the resistor Rn and the MOS capacitor Cn.

Like this, by inserting the plurality of low-pass filters LPF1 to LPFn between the power supply terminal 104 and the internal circuit 102, it is possible to reduce undesired radiant noise due to a harmonic component of a fundamental clock frequency of a clock pulse used in the internal circuit 102. However, the reduction effect has a limit. This is because the undesired radiant noise generated in the internal circuit is propagated to not only the power supply terminal 104 but also to the ground terminal 106. However, the ground potential is a reference for a potential in the circuit and is required to be constant irrespective of the operation state of the circuit, and therefore, under the present circumstances, a countermeasure for reducing the undesired radiant noise has not been taken at the ground side.

### SUMMARY OF THE INVENTION

An object of the present invention is to provide a noise reduction circuit which can reduce undesired radiant noise generated from a semiconductor device and a semiconductor device including the noise reduction circuit.

The above object is achieved by a noise reduction circuit which is used for a semiconductor device comprising an internal circuit including a circuit operating in synchronization with a clock, a power supply terminal for supplying an external power supply voltage to the internal circuit, and a ground terminal for giving a ground potential to the internal circuit, and which is characterized by comprising a plurality of low-pass filters comprised of resistors and capacitors and inserted between the power supply terminal and the internal circuit and between the ground terminal and the internal circuit, to reduce undesired radiant noise transmitted from the internal circuit.

According to the noise reduction circuit of the present invention, since the plurality of low-pass filters are inserted not only between the power supply terminal and the internal circuit but also between the ground terminal and the internal circuit, the undesired radiant noise transmitted from the internal circuit can be certainly reduced.

Besides, the above object is achieved by a semiconductor device characterized by comprising an internal circuit including a circuit operating in synchronization with a clock, a power supply terminal for supplying an external power supply voltage to the internal circuit, a ground terminal for giving a ground potential to the internal circuit, and a noise reduction circuit including a plurality of low-pass filters comprised of resistors and capacitors and inserted to a power supply line between the power supply terminal and the internal circuit and a ground line between the ground terminal and the internal circuit.

The structure of the present invention can be applied to any semiconductor devices comprising an internal circuit including a circuit operating in synchronization with a clock, and can certainly reduce the undesired radiant noise containing a harmonic component of a clock frequency transmitted from the internal circuit by the noise reduction circuit.

The semiconductor device of the present invention is characterized in that the capacitor of the noise reduction circuit is a MOS capacitor using a gate capacitance of a MOSFET. By doing so, it can be easily formed by using a general manufacturing method of a semiconductor device, and further, a desired capacitance can be formed by a relatively small area since a thin gate oxide film is used as a dielectric.

Besides, the semiconductor device of the present invention is characterized in that a ground side of the capacitor of the low-pass filter inserted to the power supply line is connected to the ground terminal, and a power supply side of the capacitor of the low-pass filter inserted to the ground line is connected to the power supply terminal. By doing so, the plurality of low-pass filters can be inserted not only between the power supply terminal and the internal circuit but also between the ground terminal and the internal circuit.

Besides, the semiconductor device of the present invention is characterized in that a ground side of the capacitor of the low-pass filter inserted to the power supply line is connected to the ground line at a side of the internal circuit, and a power supply side of the capacitor of the low-pass filter inserted to the ground line is connected to the power supply line at the side of the internal circuit. Also by this structure, the plurality of low-pass filters can be inserted not only between the power supply terminal and the internal circuit but also between the ground terminal and the internal circuit.

Moreover, the semiconductor device of the present invention is characterized in that the capacitors are disposed between the plurality of resistors disposed to the power supply line and the plurality of resistors disposed to the ground line. Also by this structure, the plurality of low-pass filters can be inserted not only between the power supply terminal and the internal circuit but also between the ground terminal and the internal circuit.

Moreover, the semiconductor device of the present invention is characterized in that an inter-terminal capacitor having a capacitance value larger than the MOS capacitor is provided between the power supply terminal and the ground terminal. By doing so, a cut-off frequency in a case where the whole noise reduction circuit is made one low-pass filter is lowered so that frequency-gain characteristics of the filter can be improved.

Besides, the above object is achieved by a semiconductor device characterized by comprising an internal circuit including a circuit operating in synchronization with a clock, a power supply terminal for supplying an external power supply voltage to the internal circuit, a ground terminal for giving a ground potential to the internal circuit, and a noise reduction circuit including low-pass filters comprised of resistors respectively inserted to a power supply line between the power supply terminal and the internal circuit and to a ground line between the ground terminal and the internal circuit, and an inter-terminal capacitor provided between the power supply terminal and the ground terminal.

According to the structure of the present invention, one resistor is formed to the power supply line between the power supply terminal and the internal circuit, one resistor is formed to the ground line between the ground terminal and the internal circuit, and one inter-terminal capacitor is formed between the power supply terminal and the ground terminal, so that the noise reduction circuit of a simple structure can be realized.

The semiconductor device of the present invention is characterized in that the inter-terminal capacitor has such a capacitance value as to make a cut-off frequency of a low-pass filter as the whole noise reduction circuit lower than an FM band. By doing so, radiant noise of the FM band generated from a semiconductor device can be reduced, and for example, it is possible to prevent erroneous channel selection in auto-tuning of an in-vehicle radio.

### BRIEF DESCRIPTION OF THE DRAWINGS

FIG. 1 shows a schematic structure of a noise reduction circuit according to an embodiment of the present invention and a semiconductor device including the noise reduction circuit.

FIG. 2 shows a schematic structure of a modified example of the noise reduction circuit according to the embodiment of the present invention and the semiconductor device including the noise reduction circuit.

FIG. 3 shows a schematic structure of another modified example of the noise reduction circuit according to the embodiment of the present invention and the semiconductor device including the noise reduction circuit.

FIG. 4 shows a schematic structure of still another modified example of the noise reduction circuit according to the embodiment of the present invention and the semiconductor device including the noise reduction circuit.

FIG. 5 shows a schematic structure of still another modified example of the noise reduction circuit according to the embodiment of the present invention and the semiconductor device including the noise reduction circuit.

FIG. 6 shows a conventional noise reduction circuit and a semiconductor device including the noise reduction circuit.

### DESCRIPTION OF THE PREFERRED EMBODIMENTS OF THE INVENTION

A noise reduction circuit according to an embodiment of the present invention and a semiconductor device including the noise reduction circuit will be described with reference to FIGS. 1 to 5. First, a schematic structure of the noise reduction circuit of this embodiment and the semiconductor device using the noise reduction circuit will be described with reference to FIG. 1.

FIG. 1 schematically shows the vicinities of a power supply terminal 4 and a ground terminal 6 of an LSI chip 1 as the semiconductor device of this embodiment. An internal circuit 2 has a not-shown built-in clock generator (oscillator), and includes a circuit operating in synchronization with a clock. In this embodiment, various digital integrated circuits, such as a microcomputer, ASIC, MCU (Memory Control Unit), or various DRAMs including SDRAM, are exemplified as the internal circuit 2. An external power supply voltage is supplied to the internal circuit 2 from the power supply terminal 4, and a ground potential of the circuit is given from the ground terminal 6.

A power supply line 8 is extended from the internal circuit 2 and is connected to the power supply terminal 4. N resistors RS1 to RSn are connected in series with the power supply line 8. Besides, an N-channel MOS capacitor CS1 formed by using a gate capacitance of an N-channel MOSFET is disposed between a connection point between the resistors RS1 and RS2 and the ground terminal 6. A gate electrode of the MOS capacitor CS1 is connected to the connection point between the resistors RS1 and RS2, and source/drain electrodes of the MOS capacitor CS1 are shorted and are connected to the ground terminal 6. A low-pass filter LPF-S1 is constituted by a CR circuit of the resistor RS1 and the N-channel MOS capacitor CS1.

Besides, an N-channel MOS capacitor CS2 is disposed between a connection point between the resistor RS2 and the resistor RS3 (not shown) and the ground terminal 6. A gate electrode of the MOS capacitor CS2 is connected to the connection point between the resistors RS2 and RS3, and source/drain electrodes of the MOS capacitor CS2 are shorted and are connected to the ground terminal 6. A low-pass filter LPF-S2 is constituted by a CR circuit of the resistor RS2 and the N-channel MOS capacitor CS2.

Hereafter, in the same way, a not-shown N-channel MOS capacitor CS(n−1) is connected between a connection point between the not-shown resistor RS(n−1) and the resistor RSn and the ground terminal 6 so that a low-pass filter LPF-S(n−1) is constituted, and an N-channel MOS capacitor CSn is connected between a connection point between the resistor RSn and the end portion of the internal circuit 2 and the ground terminal 6 so that a low-pass filter LPF-Sn is constituted. In this embodiment, n=42 and the 42 low-pass filters LPF-S1 to LPF-S42 are formed at the side of the power supply line 8.

On the other hand, a ground line 10 is extended from the internal circuit 2 and is connected to the ground terminal 6. N resistors RG1 to RGn are connected in series with the ground line 10. A P-channel MOS capacitor CG1 formed by using a gate capacitance of a P-channel MOSFET is disposed between a connection point between the resistors RG1 and RG2 and the power supply terminal 4. A gate electrode of the MOS capacitor CG1 is connected to the connection point between the resistors RG1 and RG2, and source/drain electrodes of the MOS capacitor CG1 are shorted and are connected to the power supply terminal 4. A low-pass filter LPF-G1 is constituted by a CR circuit of the resistor RG1 and the P-channel MOS capacitor CG1.

Besides, a P-channel MOS capacitor CG2 is disposed between a connection point between the resistors RG2 and RG3 (not shown) and the power supply terminal 4. A gate electrode of the MOS capacitor CG2 is connected to the connection point between the resistors RG2 and RG3, and source/drain electrodes of the MOS capacitor CG2 are shorted and are connected to the power supply terminal 4. A low-pass filter LPF-G2 is constituted by a CR circuit of the resistor RG2 and the P-channel MOS capacitor CG2.

Hereafter, in the same way, a not-shown P-channel MOS capacitor CG(n−1) is connected between a connection point between the not-shown resistor RG(n−1) and the resistor RGn and the power supply terminal 4 so that a low-pass filter LPF-G(n−1) is constituted, and a P-channel MOS capacitor CGn is connected between a connection point between the resistor RGn and the end portion of the internal circuit 2 and the power supply terminal 4 so that a low-pass filter LPF-Gn is constituted. In this embodiment, n=42 and the 42 low-pass filters LPF-G2 to LPF-G42 are formed at the ground side.

Like this, in this embodiment, not only the plurality of low-pass filters LPF-S1 to LPF-Sn are inserted between the power supply terminal 4 and the internal circuit 2, but also the plurality of low-pass filters LPF-GL to LPF-Gn are inserted between the ground terminal 6 and the internal circuit 2. The noise reduction circuit is constituted by these plurality of low-pass filters LPF-S1 to LPF-Sn and LPF-G1 to LPF-Gn.

This noise reduction circuit can reduce undesired radiant noise due to a harmonic component of a fundamental frequency of a clock pulse used in the internal circuit 2, from not only the side of the power supply terminal 4 but also the side of the ground terminal 6. By this, it becomes possible to certainly reduce the undesired radiant noise generated from the semiconductor device.

Specifically, when the resistance value of each of the resistors RS1 to RS42 and RG1 to RG42 in the low-pass filters LPF-S1 to LPF-S42 and LPF-G1 to LPF-G42 is made 244 mΩ, and the capacitance value of each of the MOS capacitors CS1 to CS42 and CG1 to CG42 is made 7.38 pF, it is possible to halve a peak level of the undesired radiant noise in the FM band from −62 dB to −67 dB.

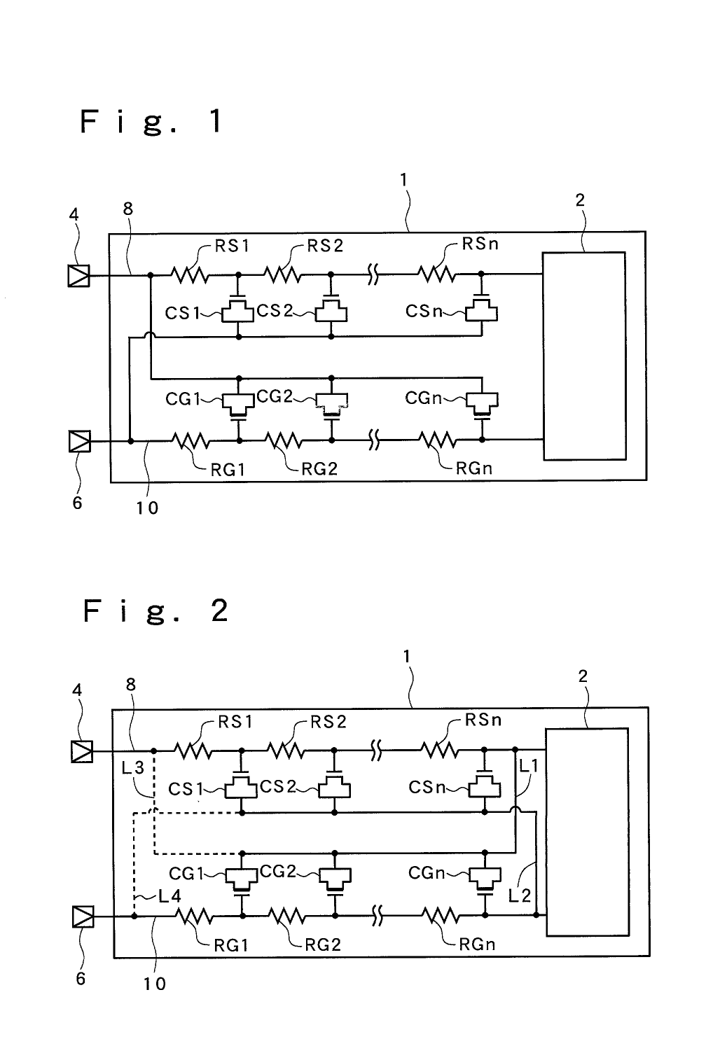

Next, a modified example of the noise reduction circuit and the semiconductor device including the noise reduction circuit according to this embodiment will be described with reference to FIG. 2. FIG. 2 shows a state where the ground side wiring of the low-pass filters LPF-SL to LPF-S42 is supplied from the side of the internal circuit 2, and the power supply side wiring of the low-pass filters LPF-GL to LPF-G42 is supplied from the side of the internal circuit 2. In FIG. 2, if wiring lines L3 and L4 indicated by broken lines are used, it becomes the same as the structure shown in FIG. 1. In the circuit shown in FIG. 2, instead of the wiring lines L3 and L4, wiring lines L1 and L2 are used to constitute the noise reduction circuit.

The wiring line L1 is extended from a connection point between the low-pass filter LPF-Sn and the internal circuit 2 and is connected to the MOS capacitors CG1 to CGn. The wiring line L2 is extended from a connection point between the low-pass filter LPF-Gn and the internal circuit 2 and is connected to the MOS capacitors CS1 to CSn. Also by the structure of the noise reduction circuit shown in FIG. 2, a noise reduction effect similar to that shown in FIG. 1 can be obtained.

Next, another modified example of the noise reduction circuit and the semiconductor device including the noise reduction circuit according to this embodiment will be described with reference to FIG. 3. A semiconductor device shown in FIG. 3 is characterized in that in the semiconductor device shown in FIG. 2, an inter-terminal capacitor (MOS capacitor) 14 is added between the power supply terminal 4 and the ground terminal 6 at the input side. The added MOS capacitor 14 has a capacitance value of, for example, 800 pF, so that a cut-off frequency of a low-pass filter as the whole noise reduction circuit becomes lower than the FM band.

The structure shown in FIG. 3 is effective in a case where for example, in the semiconductor device shown in FIG. 2, a resistance value of each of the resistors RS and RG of the noise reduction circuit can not be made high to prevent a power supply voltage drop in the internal circuit 2, or in a case where the capacitance of each of the MOS capacitors CS and CG can not be increased to prevent the chip area from enlarging to obtain large capacitance.

By adding the MOS capacitor 14, a cut-off frequency in the case where the whole noise reduction circuit is made one low-pass filter is lowered and frequency-gain characteristics of the filter can be improved.

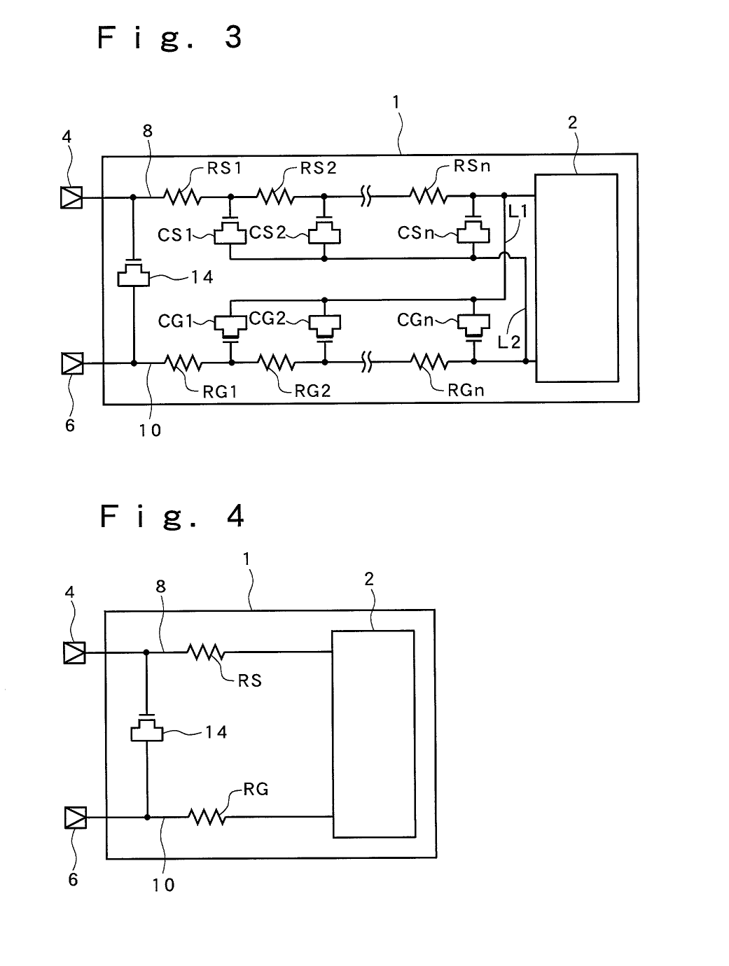

It is also possible to make a structure shown in FIG. 4 by further modifying the structure shown in FIG. 3. In the semiconductor device shown in FIG. 4, substantially one resistor RS is formed to the power supply line 8, and substantially one resistor RG is formed to the ground line 10. The MOS capacitors CS and CG are not formed, but a MOS capacitor 14 is formed between the power supply terminal 4 and the ground terminal 6. Also by this structure, a noise reduction effect similar to that of FIG. 3 can be obtained.

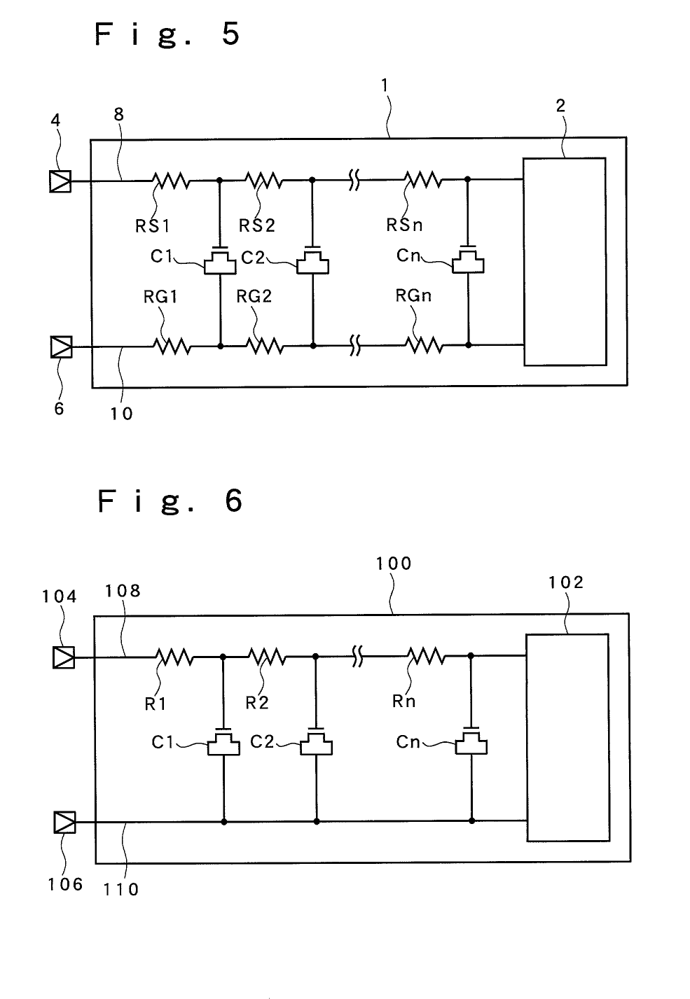

Next, a still another modified example of the noise reduction circuit and the semiconductor device including the noise reduction circuit according to this embodiment will be described with reference to FIG. 5. In a semiconductor device shown in FIG. 5, a plurality of resistors RS1 to RSn are disposed to the power supply line 8 between the power supply terminal 4 and the internal circuit 2, and a plurality of resistors RG1 to RGn are disposed to the ground line 10 between the ground terminal 6 and the internal circuit 2. Then, the semiconductor device is characterized by comprising at least two MOS capacitors C between the resistors RS1 to RSn disposed to the power supply line 8 and the resistors RG1 to RGn disposed to the ground line 10. In FIG. 5, MOS capacitors C1 to Cn are formed between the respective resistors RS1 to RSn and the respective resistors RG1 to RGn and between the resistors RSn and RGn and the internal circuit 2.

Also by this structure, an excellent noise reduction effect as compared with the conventional structure can be obtained. Incidentally, in the noise reduction circuit shown in FIG. 5, an inter-terminal capacitor (MOS capacitor) 14 as explained with reference to FIG. 3 maybe naturally added between the power supply terminal 4 and the ground terminal 6.

As described above, according to this embodiment, by inserting the low-pass filters to both the power supply line between the power supply terminal and the internal circuit and the ground line between the ground terminal and the internal circuit, the undesired radiant noise can be certainly reduced, and it is possible to realize the highly reliable noise reduction circuit suitably used for an in-vehicle electronic equipment requiring an EMI countermeasure, and the semiconductor device including the noise reduction circuit.

The present invention is not limited to the above embodiment, but various modifications can be made.

For example, in the above embodiment, the resistor RSn and the N-channel MOS capacitor are connected to constitute the low-pass filter LPF-Sn, and the resistor RGn and the P-channel MOS capacitor CGn are connected to constitute the low-pass filter LPF-Gn. However, the present invention is not limited to this, but the conductivity type of the MOS capacitor may be reversed, or the same conductivity type may be naturally adopted in the whole noise reduction circuit. Besides, in the above embodiment, although the MOS capacitor is used as the capacitor of the CR circuit constituting the low-pass filter, the present invention is not limited to this, but metal layers opposite to each other through an insulating film in the semiconductor device may be naturally used as the capacitor.

As described above, according to the present invention, undesired radiant noise generated from a semiconductor device can be reduced. Besides, it is possible to realize a semiconductor device in which undesired radiant noise is reduced and which has high reliability.

What is claimed is:

1. A noise reduction circuit for use in a semiconductor device which comprises an internal circuit including a circuit operating in synchronization with a clock, a power supply terminal for supplying an external power supply voltage to the internal circuit, and a ground terminal for giving a ground potential to the internal circuit, the noise reduction circuit comprising:
a plurality of low-pass filters comprised of resistors and capacitors and inserted between the power supply terminal and the internal circuit and between the ground terminal and the internal circuit, to reduce undesired radiant noise transmitted from the internal circuit.

2. A semiconductor device comprising:
an internal circuit including a circuit operating in synchronization with a clock;
a power supply terminal for supplying an external power supply voltage to the internal circuit;
a ground terminal for giving a ground potential to the internal circuit; and
a noise reduction circuit including a plurality of low-pass filters comprised of resistors and capacitors and inserted to a power supply line between the power supply terminal and the internal circuit and a ground line between the ground terminal and the internal circuit.

3. A semiconductor device according to claim 2, wherein the capacitor of the noise reduction circuit is a MOS capacitor using a gate capacitance of a MOSFET.

4. A semiconductor device according to claim 2, wherein a ground side of the capacitor of the low-pass filter inserted to the power supply line is connected to the ground terminal, and
a power supply side of the capacitor of the low-pass filter inserted to the ground line is connected to the power supply terminal.

5. A semiconductor device according to claim 3, wherein a ground side of the capacitor of the low-pass filter inserted to the power supply line is connected to the ground line at a side of the internal circuit, and a power supply side of the capacitor of the low-pass filter inserted to the ground line is connected to the power supply line at the side of the internal circuit.

6. A semiconductor device according to claim 5, further comprising an inter-terminal capacitor having a capacitance value larger than the MOS capacitor and provided between the power supply terminal and the ground terminal.

7. A semiconductor device according to claim 6, wherein the inter-terminal capacitor has the capacitance value to make a cut-off frequency of a low-pass filter as the whole noise reduction circuit lower than an FM band.

8. A semiconductor device according to claim 3, wherein the capacitors are disposed between the plurality of resistors disposed to the power supply line and the plurality of resistors disposed to the ground line.

9. A semiconductor device according to claim 8, further comprising an inter-terminal capacitor having a capacitance value larger than the MOS capacitor and provided between the power supply terminal and the ground terminal.

10. A semiconductor device according to claim 9, wherein the inter-terminal capacitor has the capacitance value to make a cut-off frequency of a low-pass filter as the whole noise reduction circuit lower than an FM band.

11. A semiconductor device comprising:
an internal circuit including a circuit operating in synchronization with a clock;
a power supply terminal for supplying an external power supply voltage to the internal circuit;
a ground terminal for giving a ground potential to the internal circuit; and
a noise reduction circuit including low-pass filters comprised of resistors respectively inserted to a power supply line between the power supply terminal and the internal circuit and to a ground line between the ground terminal and the internal circuit, and an inter-terminal capacitor provided between the power supply terminal and the ground terminal.

12. A semiconductor device according to claim 11, wherein the inter-terminal capacitor has a capacitance value to make a cut-off frequency of a low-pass filter as the whole noise reduction circuit lower than an FM band.
